(19) United States
(12) Patent Application Publication
(10) Pub. No.: US 2013/0221997 A1
(43) Pub. Date: Aug. 29, 2013

(54) METHOD AND DEVICE FOR MONITORING THE INSULATION RESISTANCE IN AN UNGROUNDED ELECTRICAL NETWORK

(71) Applicants: Vicente Garcia Alvarrez, Stuttgart (DE); Andreas Trautmann, Horgenzell (DE); Dragan Mikulec, Erlangen (DE)

(72) Inventors: Vicente Garcia Alvarrez, Stuttgart (DE); Andreas Trautmann, Horgenzell (DE); Dragan Mikulec, Erlangen (DE)

(21) Appl. No.: 13/704,906

(22) PCT Filed: Apr. 27, 2011
(86) PCT No.: PCT/EP2011/056654

§ 371 Date: May 9, 2013

(30) Foreign Application Priority Data
Jun. 15, 2010 (DE) 10 2010 030 079.9

(51) Int. Cl. G01R 27/14

(52) U.S. Cl. CPC G01R 27/14
USPC 324/709

(57) ABSTRACT

A method and a device for monitoring the insulation resistance in an ungrounded electrical network having a constant-voltage d.c. link and at least one inverter, connected to it, for controlling an n-phase electrical consumer in an n-phase network. A voltage to be monitored, is determined during operation of the consumer, which represents a voltage fluctuation of supply voltage potentials of the constant-voltage d.c. link with respect to a reference potential. In addition, a variable characterizing an electrical frequency of the electrical consumer is determined, particularly an electrical angular speed of the electrical consumer. A first spectral amplitude of the voltage to be monitored at the n-fold electrical frequency of the electrical consumer, is compared to a first reference value, and detects a symmetrical insulation error in the constant-voltage d.c. link or the n-phased network, if the comparison yields a deviation of the first spectral amplitude from the first reference value.

### FIELD

The present invention relates to a method and a device for monitoring the insulation resistance in an ungrounded electrical network.

### BACKGROUND INFORMATION

To drive hybrid or electric vehicles, electric machines are used, generally, in the form of polyphase machines, which are operated in connection with rectifiers, that are frequently also designated as inverters. The electrical energy for the operation of the electric machine is supplied, in this context, by a power supply that is not grounded, and is separate from the vehicle electrical system of the vehicle, for example, in the form of a powerful high-voltage battery. The ungrounded electrical network created in this way, frequently also designated as an IT network (Isolé Terre), reduces the endangering of service personnel, for example, since, in the case of an individual error, for example, no closed circuit is set up. In addition, when an individual fault occurs, the operation does not have to be set so that an insulation fault is able to be reported without this already resulting in a system failure. For this it is required, however, that the insulation resistance of the electrical network is also monitored, continuously or at least periodically during the operation of the vehicle.

A method is described in German Patent Application No. DE 10 2006 031 663 B3, for measuring the insulation resistance in an IT network having a constant-voltage d.c. link and at least one self-commutated current converter as well as a measuring arrangement for measuring the link voltage with respect to ground voltage, in which an offline and an online measurement are provided. During the offline measurement, during which all power switches of the current converter are closed, potentials Up and Um as well as the link voltage are measured, in this context, and from this the insulation resistance is determined. During the online measurement, potentials Up and Um are measured and the curve over time of the measurements is evaluated. For this, the two potentials are added, in particular, the sum is Fourier-transformed and the change in the frequency spectrum is evaluated in its curve over time.

A method is described in European Patent No. EP 1 909 369 A2 for insulation monitoring for current converter systems that are in operation, the current converter system including a voltage source d.c. link having at least one positive branch and one negative branch, at least one electrical unit that has at least two phase connections, and at least one converter having switching elements for the electrical connection of the phase connections to the positive branch or the negative branch of the voltage source d.c. link. It is provided in this instance that an operating state of the converter, during which the current converter is in operation, and is feeding the electrical unit, which is also in normal operation in this context, is determined by recording parameters of a converter control. In addition, at least one of the voltages of the positive branch or the negative branch is measured. Finally, according to the measured voltage or voltages and the operating state of the current converter, insulation defects are determined on the voltage source d.c. link and/or on the phase connections and/or on the electrical unit.

### SUMMARY

The present invention provides an example method for monitoring the insulation resistance in an ungrounded electrical network having a constant-voltage d.c. link and at least one inverter, that is connected to it, for controlling an n-phase electrical user in an n-phase network, with n>1. In this context, during the operation of the user, a voltage to be monitored is first determined which represents a voltage fluctuation of supply voltage potentials of the constant-voltage d.c. link with respect to a reference potential. In addition, a variable characterizing an electrical frequency of the electrical consumer is determined, particularly an electrical angular speed of the electrical consumer. Subsequently, a first spectral amplitude of the voltage to be monitored at the n-fold electrical frequency of the electrical consumer is determined, the first spectral amplitude of the voltage to be monitored is compared to a first reference value, and a symmetric insulation fault is detected in the constant-voltage d.c. link or the n-phased network, if the comparison yields a deviation of the first amplitude value from the first reference value.

During the operation of the electric consumer, and thus, during the operation of the inverter, alternating voltage portions are superposed on the direct voltage potentials of the supply voltage buses of the constant-voltage d.c. link, which lead to a voltage fluctuation of the supply voltage potentials of the constant-voltage d.c. link with respect to a reference potential which, for example, is formed by a vehicle body.

The present invention is based on the basic idea that a symmetric insulation fault in the constant-voltage d.c. link, frequently also designated as traction network, or in the n-phase network, has effects on the spectral distribution of a voltage which represents this voltage fluctuation of the supply voltage potentials of the constant-voltage d.c. link with respect to the reference potential. In this context, the spectral distribution changes to the extent that, in contrast to normal operation, that is, in contrast to operation without insulation fault, signal portions are yielded even in response to the n-fold electrical frequency of the electric consumer, or expressed differently, in response to the nth harmonic of the electrical frequency of the consumer. By evaluation of the (first) spectral amplitude belonging to the n-fold electrical frequency, a symmetric insulation fault is consequently able to be reliably detected using low switching technology effort. In this present text and in the following, the term “symmetric insulation fault” designates a deterioration in the insulation resistance, which occurs on both supply voltage buses of the constant-voltage d.c. links or in all phases of the n-phase network in the same manner, which may be the case, for example, as a result of aging processes.

The method according to the present invention has the additional advantage that monitoring is able to take place continuously or periodically (quasi-continuously) during operation of the electrical consumer, and thus of the inverter. By further analysis of the deviation of the first spectral amplitude from the first reference value, it may also be determined whether the symmetric insulation fault has appeared in the constant-voltage d.c. link or in the n-phase network. Thus, a symmetric insulation fault is detected in the constant-voltage d.c. link if the first spectral amplitude is less than the reference value and a symmetric insulation fault is detected in the n-phase network if the first spectral amplitude is greater than the reference value.

In order also to make possible the detection of asymmetric insulation faults, that is, deteriorations in the insulating resistance by which only one supply voltage bus of the constant-voltage d.c. link or only one part of the phases of the n-phase network are affected, according to one specific embodiment of the present invention, it is provided to determine a second spectral amplitude of the voltage to be monitored of the (1-fold) electrical frequency of the electrical consumer, to compare this to a second reference value and to detect an asymmetric insulation fault in the n-phase network if the comparison yields a deviation of the second spectral amplitude from the second reference value.

Just as a symmetric insulation fault, an asymmetric insulation fault also has effects upon the spectral distribution of the voltage to be monitored. In contrast to a symmetric fault, the change does not, however, show by the appearance of an additional signal portion in the range of the n-fold electrical frequency of the consumer, but by a change in the signal portion in the range of the (1-fold) electrical frequency. By evaluation of the (second) spectral amplitude appearing in response to this frequency, an asymmetric insulation fault is consequently able to be reliably detected using low switching technology effort. Both for symmetric and for asymmetric insulation faults, it is true that the absolute quantity of the change of the first and the second spectral amplitude is in each case a measure for the deterioration of the insulation resistance, so that a quantitative statement on the change in the insulation resistance is also possible.

For the voltage to be monitored, it is only decisive that it represents the voltage fluctuation of the supply voltage potentials of the constant-voltage d.c. link with respect to the reference potential. This criterion is satisfied by different voltages in the overall system.

According to a first specific embodiment of the present invention, at least one of the supply voltage potentials of the constant-voltage d.c. link is measured with respect to a reference potential and the link voltage of the constant-voltage d.c. link is measured, and the voltage that is to be monitored is determined by summing up the measured voltages. In the same way, both supply voltage potentials of the constant-voltage d.c. link may also be measured with respect to the reference potential, and from this, the voltage to be monitored may be determined by forming the summation.

According to an additional specific embodiment of the present invention, a voltage divider, particularly a symmetric voltage divider, is connected between the supply voltage potentials of the constant-voltage d.c. link. In this case, a first measured voltage, which is measured at a central tap of the voltage divider, may be used as the voltage to be monitored. This specific embodiment has the advantage that only one single voltage measurement is required and no additional computing effort is required for determining the voltage to be monitored. Moreover, the measuring range is able to be adjusted to a maximum fluctuation amplitude, which leads to increased measurement accuracy. Instead of the voltage itself, another variable, such as current, perhaps, may be measured which characterizes the voltage.

In a further specific embodiment of the present invention, the phases of the n-phase network are joined via impedances in an (artificial) star point. At the star point, a second measured voltage may then be measured with respect to the reference potential, which may be deducted from a star point voltage that comes about at the star point opposite the half link voltage. The auxiliary voltage calculated in this manner also represents the voltage fluctuation of the supply voltage potentials of the constant-voltage d.c. link with respect to the reference potential, and may thus be used as the voltage to be monitored. In this specific embodiment too, only a single voltage measurement is required, the measuring range being able to be adjusted to a maximum fluctuation amplitude. Alternatively to the direct measurement of the measured voltage, a variable derived from the measured voltage, which characterizes the voltage, may also be measured, in this instance.

According to an additional specific embodiment of the present invention, it is provided that the reference values represent spectral amplitudes of the voltage to be monitored at the corresponding electrical frequencies, in normal operation without insulation faults.

To determine the spectral amplitudes, according to one specific embodiment of the present invention, it is provided that one should form a frequency spectrum of the voltage to be monitored, particularly with the aid of a fast Fourier transformation (FFT).

Alternatively to this, the voltage to be monitored may also be bandpass-filtered, and the spectral amplitudes may be determined with the aid of the filtered voltage that is to be monitored. Both methods permit a determination of the spectral amplitudes using relatively little switching technology effort.

If only one fault message is output as a result of a detected insulation fault, the entire system has to be checked for possible faults for the removal of the fault, for instance, in a repair station. It is therefore desirable besides the pure fault message, also to provide information as to in which region of the overall system the insulation fault has occurred.

If an asymmetric insulation fault occurs in one of the supply voltage buses of the constant-voltage d.c. link, a direct voltage offset comes about between the absolute amounts of the two supply voltage potentials of the constant-voltage d.c. link. According to one specific embodiment of the present invention, this offset is determined, for example, with the aid of a low pass filtering of the voltage that is to be monitored. If this direct voltage offset reaches a specified boundary value, it may be concluded that an asymmetric insulation fault has to be present in the area of one of the supply voltage buses of the constant-voltage d.c. link. Then the respectively affected supply voltage bus may also still be detected as a function of the sign of the direct voltage offset.

If the insulation fault is in the region of the n-phase network, it is of advantage to determine a phase position of the voltage that is to be monitored and phase positions of phase voltages of the electrical consumer. As a function of a relative phase position of the voltage that is to be monitored with respect to the phase positions of the phase voltages, it is then possible to determine whether a single-phase or a multiphase asymmetric insulation fault is present in the area of the n-phase network. In addition, the affected phases may also be recognized.

For the detection of a two-phase asymmetric insulation fault in the area of the two-phase network, an energy content of the voltage that is to be monitored may be determined additionally or alternatively. Since the energy content decreases with an increasing number of the phases affected by the insulation fault, it may be detected, as a function of the energy content, how many phases are affected by the insulation fault.

The effective value of the voltage that is to be monitored also decreases with an increasing number of insulation faults. Consequently, it may also be determined, as a function of the effective value, how many phases are affected by the insulation fault.

The present invention also provides an example device for monitoring the insulation resistance in an ungrounded network, the network including a constant-voltage d.c. link, an n-phase network having an n-phase electrical consumer and at least one inverter connected to the constant-voltage d.c. link for controlling the electrical consumer. In this context, the example device according to the present invention includes:
at least two measuring devices for measuring a supply voltage potential of the constant-voltage d.c. link and a link voltage, or of the two supply voltage potentials of the constant-voltage d.c. link,
a computational unit for determining a voltage that is to be monitored by the formation of a sum of the measured voltages, the voltage that is to be monitored representing a voltage fluctuation of the supply voltage potentials of the constant-voltage d.c. link with respect to a reference potential, and
an evaluation unit, which determines a first spectral amplitude of the voltage to be monitored at the n-fold electrical frequency of the electrical consumer is determined, the first spectral amplitude is compared to a first reference value, and a symmetric insulation fault is detected in the constant-voltage d.c. link or the n-phased network, if the comparison yields a deviation of the first spectral amplitude from the first reference value.

The computational unit and the evaluation unit may also be implemented, in this instance, as a single unit, in the form of a microcontroller, for example.

If a voltage divider, particularly a symmetric voltage divider, is provided in the constant-voltage d.c. link, which is connected between the supply voltage potentials of the constant-voltage d.c. link, and has a center tap, a single voltage measuring device is sufficient for measuring a first measured voltage at the center tap of the voltage divider. This first measured voltage then represents directly the voltage that is to be monitored, which represents the voltage fluctuation of the supply voltage potentials with respect to the reference potential. That being the case, the computational unit may also logically be omitted. Alternatively to the direct measurement of the measured voltage, another variable derived from the measured voltage, which thus characterizes the measured voltage, may also be measured.

If the phases of the n-phase network are joined via impedances in an (artificial) star point, a single voltage measuring device is sufficient, which measures a second measured voltage at the star point with respect to a reference potential. A computational unit then forms an auxiliary voltage by a difference formation between a star point voltage, which comes about at the star point with respect to a half link voltage, and the second measured voltage. This auxiliary voltage then represents a voltage fluctuation of the supply voltage potentials of the constant-voltage d.c. link with respect to a reference potential. Alternatively to the direct measurement of the second measured voltage, a variable derived from this measured voltage, which thus characterizes the second measured voltage, may also be measured.

Further features and advantages of specific embodiments of the present invention result from the following description with reference to the figures.

### BRIEF DESCRIPTION OF THE DRAWINGS

FIG. 1 shows a schematic block diagram of an ungrounded network having a constant-voltage d.c. link, an inverter connected to it, a 3-phase electric machine and measuring devices according to a first specific embodiment of the present invention.

FIG. 2 shows a schematic block diagram of an ungrounded network having a constant-voltage d.c. link, an inverter connected to it, a 3-phase electric machine and a measuring device according to a second specific embodiment of the present invention.

FIG. 3 shows a schematic block diagram of an ungrounded network having a constant-voltage d.c. link, an inverter connected to it, a 3-phase electric machine and a measuring device according to a third specific embodiment of the present invention.

FIG. 4 shows a graphic representation of the curve over time of the voltage to be monitored in normal operation without insulation faults.

FIG. 5 shows a graphic representation of the frequency spectrum of the voltage to be monitored, according to FIG. 4.

FIG. 6 shows a graphic representation of the curve over time of the voltage to be monitored, in response to the appearance of a single-phase asymmetric insulation fault in the 3-phase network.

FIG. 7 shows a graphic representation of the frequency spectrum of the voltage to be monitored, according to FIG. 6.

FIG. 8 shows a graphic representation of the curve over time of the voltage to be monitored, in response to the appearance of a single-phase asymmetric insulation fault in the 3-phase network.

FIG. 9 shows a graphic representation of the frequency spectrum of the voltage to be monitored, according to FIG. 8.

FIG. 10 shows a graphic representation of the curve over time of the voltage to be monitored, in response to the appearance of a two-phase asymmetric insulation fault in the 3-phase network.

### DETAILED DESCRIPTION OF EXAMPLE EMBODIMENTS

In the figures, identical or functionally equivalent components are each characterized by the same reference numeral.

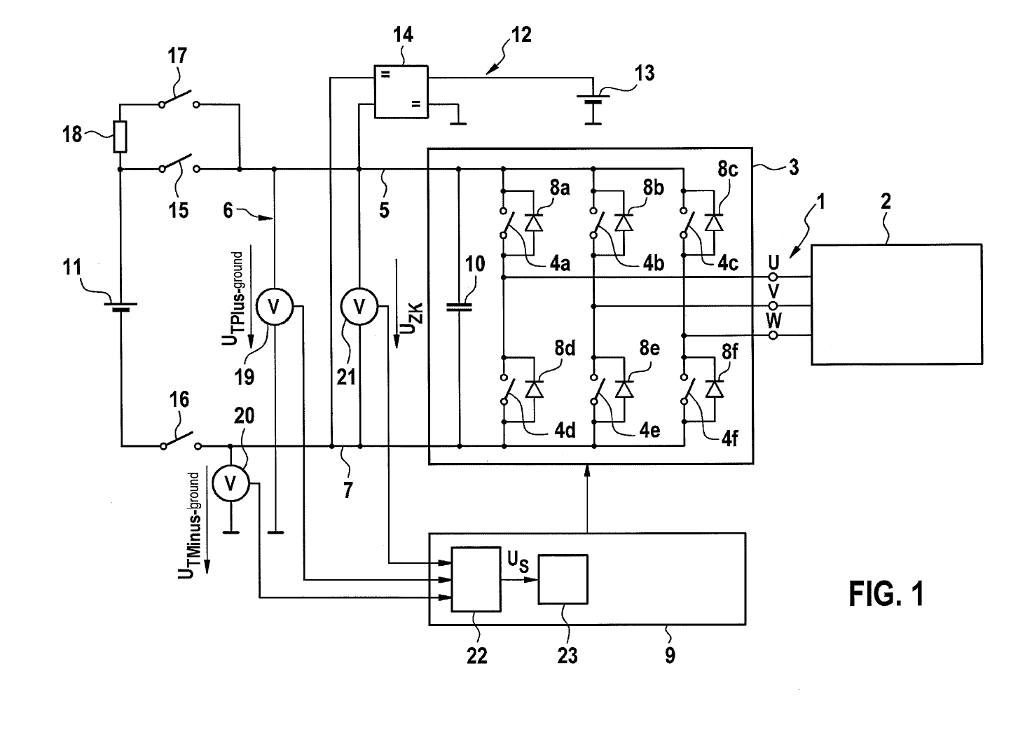

FIG. 1 shows a schematic representation of a 3-phase network 1 having a three-phase electric machine 2, which may be designed as a synchronous machine, an asynchronous machine or a reluctance machine, for example, having a pulse-controlled inverter 3 connected to it. Pulse-controlled inverter 3 includes switching elements 4a-4f in the form of power switches, which are connected to individual phases U, V, W of the electric machine 2, and phases U, V, W switch either from a positive supply voltage potential T+ that is present at a positive supply voltage bus 5 of a constant-voltage d.c. link 6 or a negative supply voltage potential T− that is present at a negative supply voltage bus 7 of constant-voltage d.c. link 6. Switching elements 4a-4c connected to positive supply voltage bus 5 are also designated, in this context, as “high-side switch” and switches 4d-4f connected to negative supply voltage bus 7 are also designated as “low-side switch”, and may, for instance, be designed as an insulated gate bipolar transistor (IGBT) or as a metal oxide semiconductor field effect transistor (MOSFET). Furthermore, pulse-controlled inverter 3 includes several free-wheeling diodes 8a-8f, which are situated respectively in parallel to one of switching elements 4a-4f.

Pulse-controlled inverter 3 determines the performance and the manner of operation of electric machine 2, and is appropriately controlled by a control unit 9, for instance, in the form of a microcontroller. Electric machine 2, in this context, may be operated optionally in motor or generator operation.

In addition, pulse-controlled inverter 3 includes a so-called intermediate circuit capacitor 10, which is used generally to stabilize the voltage of a high-energy store, in the form of a high-voltage battery 11, in constant-voltage d.c. link 6. A vehicle electrical system 12 of the vehicle, having a low-voltage energy store in the form of a low-voltage battery 13, is connected in parallel to intermediate circuit capacitor 6 via a d.c. voltage transformer 14.

Electric machine 2 is designed to be three-phase in the exemplary embodiment shown, but may also have only two or more than three phases. Preferably, however, the number of phases is equal to three or at least divisible by three.

For service purposes, for example, it is required to separate high-voltage battery 11 in the at-rest state from constant-voltage d.c. link 6, that is frequently also designated as traction network or high-voltage circuit. For this purpose, two main contactors 15 and 16 as well as a precharge contactor 17 are provided. The precharge contactor, in this context, enables a current-limited charging of the intermediate circuit capacitor via a precharge resistor 18.

Furthermore, measuring devices 19, 20 and 21 are provided, with the aid of which a voltage U_{TPlus-ground} between positive supply voltage potential T+ and a reference potential, for instance, in the form of a vehicle ground formed by the vehicle body, a voltage U_{TMinus-ground} between negative supply voltage potential T− and the reference potential or a link voltage U_{ZK} at intermediate circuit capacitor 10 are able to be measured. It should be pointed out that it is sufficient for the applicability of the present invention to provide two of the three measuring devices 19, 20 and 21 shown. Here, the term “voltage measurement” basically also include the measurement of a variable characterizing the voltage, such as the current.

Measured voltages U_{TPlus-ground}, U_{TMinus-ground} at supply voltage buses 5 and 7 and link voltage U_{ZK} are supplied, if necessary after a suitable signal processing, which may include, for example, an A/D conversion, to a computational unit 22 which, in the exemplary embodiment shown, is integrated into control unit 9, but may also alternatively be implemented as a stand-alone unit.

Computational unit 22 calculates a summed voltage U_{S}, where

U_{S}=U_{ZK}−|2·U_{TPlus-ground}|

or

U_{S}=U_{ZK}−|2·U_{TMinus-ground}|

or

U_{S}=|U_{TMinus-ground}|−|U_{TPlus-ground}|.

This summed voltage U_{S} thus represents a voltage fluctuation of supply voltage potentials T+ and T− of constant-voltage d.c. link 6 with respect to the reference potential.

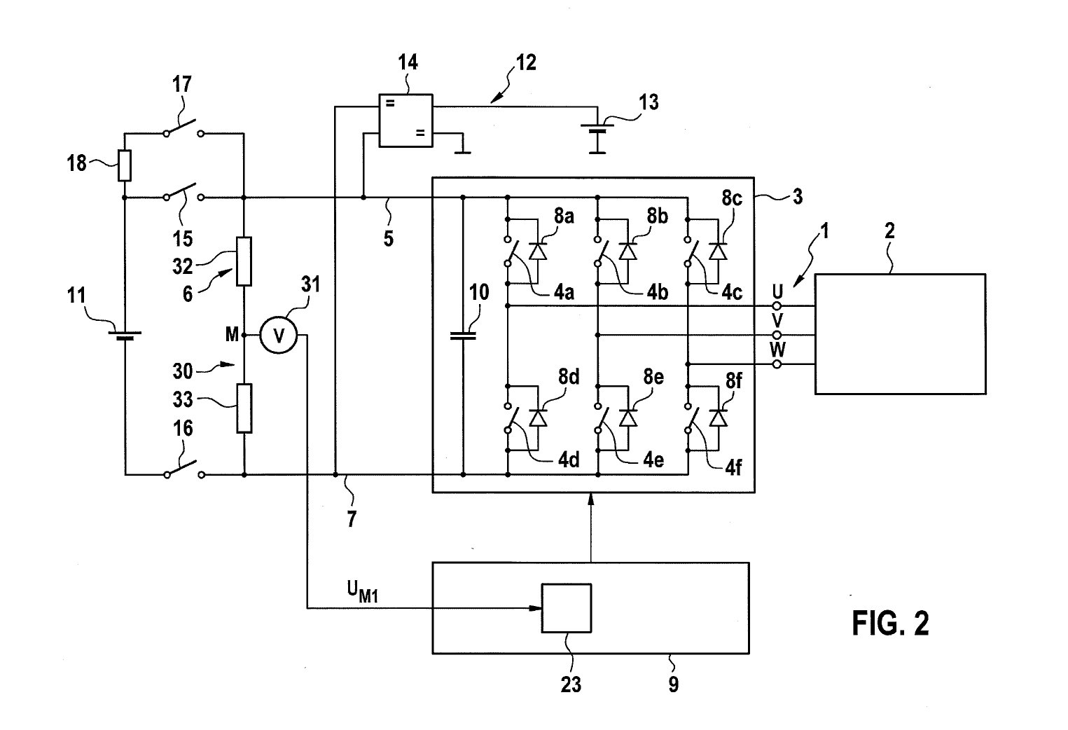

Alternatively to the specific embodiment shown in FIG. 1, having at least two of the three measuring devices 19, 20 and 21, a voltage divider 30 may also be provided in constant-voltage d.c. link 6 in parallel to intermediate circuit capacitor 10, which is preferably designed to be symmetric (cf. FIG. 2). At center tap M, with the aid of a measuring device 31, a first measured voltage U_{M1} may then be measured with respect to the reference potential, and this will directly represent a voltage fluctuation of supply voltage potentials T+ and T− of constant-voltage d.c. link 6 with respect to the reference potential. In this context, as is shown, voltage divider 30 may be formed of ohmic resistors 32 and 33 or also with the aid of capacitors and/or inductances. What is decisive for the applicability is only the voltage-dividing function. Of course, voltage divider 30 may also be developed from more than two components. In that case, too, a variable only characterizing first measured voltage U_{M1} is able to be measured.

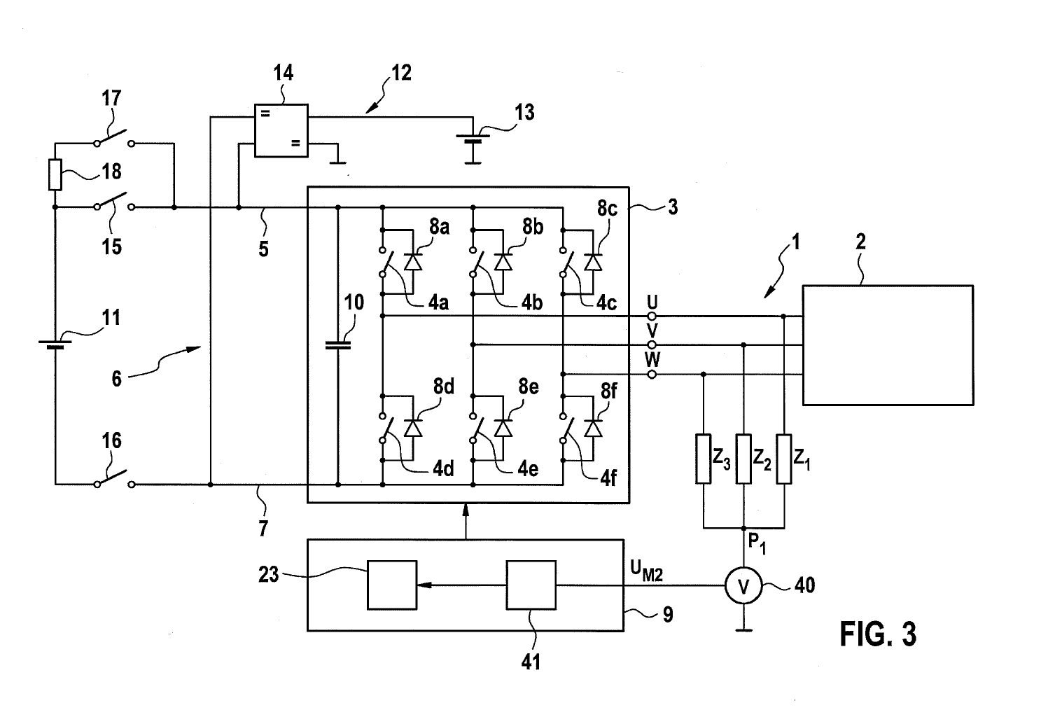

Alternatively to the specific embodiment shown in FIG. 1, having at least two of the three measuring devices 19, 20 and 21, phases U, V, W in 3-phase network 1 may also be joined via impedances Z₁, Z₂ and Z₃ to form an (artificial) star point P1 (cf. FIG. 3). In this case, a second measuring voltage U_{M2} may be measured at star point P1, with the aid of a measuring device 40, with respect to the reference potential. For a symmetric constant-voltage d.c. link 6, at supply voltage buses 5 and 7 there is a drop by in each case of half the link voltage ½*U_{ZK} with respect to the reference potential, at least based on the insulation resistors present. As a result, the potential at the star point fluctuates in a previously known manner about half the link voltage ½*U_{ZK}. If the second measured voltage U_{M2} is subtracted with the aid of a computational unit 41 from the previously known star point voltage between star point P1 and half the link voltage ½*U_{ZK}, one obtains an auxiliary voltage U_{H}, which also represents the voltage fluctuation of supply voltage potentials T+ and T− of constant-voltage d.c. link 6 with respect to the reference potential. Impedances Z₁, Z₂, Z₃ may be formed, in this context, by ohmic resistors or also with the aid of capacitors and/or inductances.

The further part of the example method is now explained starting from a specific embodiment shown in FIG. 1, in which the summed voltage US is used as the voltage that is to be monitored. However, the example method according to the present invention may be used analogously for first measured voltage U_{M1} according to FIG. 2 or auxiliary voltage U_{H} according to FIG. 3.

By an evaluation unit 23, which in the exemplary embodiment shown in FIG. 1 is integrated into control unit 8, but alternatively to this may also be implemented as a stand-alone unit, voltage U_{S}, that is to be monitored, is submitted to a frequency transformation, preferably a fast Fourier transformation (FFT), so as to calculate in this manner the frequency spectrum of the voltage that is to be monitored. By the evaluation of the absolute value spectral amplitudes |U_{S}(jω)| at specified electrical frequencies or angular velocities, an insulation fault may then be detected according to the present invention. In this instance, however, the specified electrical frequencies or the angular speeds are not fixed values, but are a function of an electrical angular speed ωₑₗ of electric machine 2, which is proportional to the electrical frequency of electric machine 2.

Therefore, a variable is determined characterizing the electrical frequency of electric machine 2, such as electrical angular speed ωₑₗ. This determination may take place based on measuring technology results. However, the electrical frequency of electric machine 2 is also frequently specified, so that it is known ahead of time.

An insulation fault, that is, a deterioration of the insulation resistance, becomes noticeable in that the spectral amplitude U_{S}(jK·ωₑₗ) changes in absolute amount at certain frequencies. Depending on whether a symmetric or an asymmetric insulation fault is involved, the change in the spectral amplitude at the 3-fold electrical angular speed is ωₑₗ, that is, at K=3, or at the (1-fold) electrical angular speed is ωₑₗ, that is, at K=1. However, this relationship will be explained in greater detail below. The change in absolute amount of the spectral amplitude, in this instance, is in each case a measure for the deterioration of the insulation resistance.

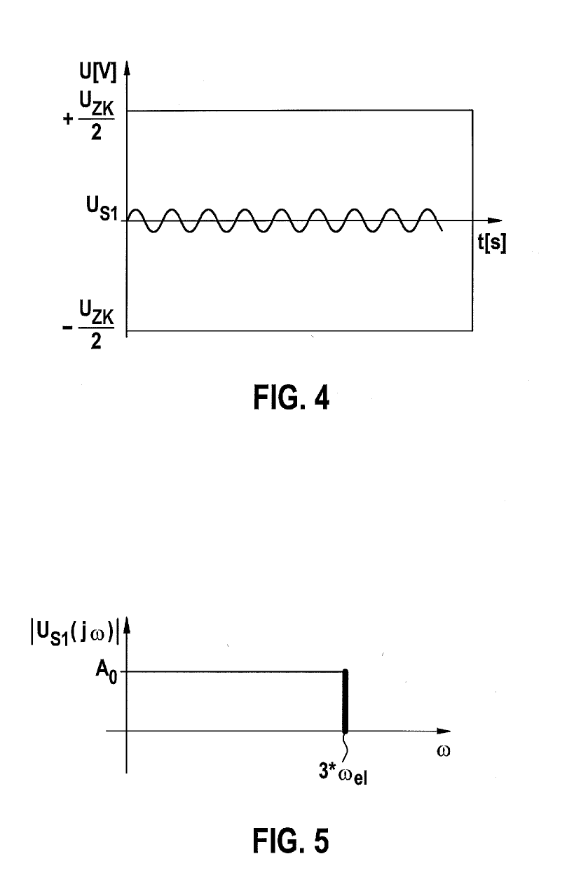

FIG. 4 shows the curve over time of summed voltage U_{S} in normal operation of electric machine 2, and with that, of pulse-controlled inverter 3, without insulation faults. Summed voltage US runs, in this instance, in the form of an alternating voltage about a zero line, which corresponds to the reference potential, that is, for example, the vehicle ground. This curve comes from the fact that, during the operation of the pulse-controlled inverter, alternating voltage components are superposed on voltages U_{TPlus-ground} and U_{TMinus-ground} between supply voltage buses 5 and 7 and the reference potential.

A fast Fourier transformation of the summed voltage shown in FIG. 4 yields a spectral distribution (frequency spectrum) shown schematically in FIG. 5. In this context, one may see that for (1-fold) electrical angular speed ωₑₗ no signal portion is present and for 3-fold electrical angular speed 3*ωₑₗ a signal portion having a spectral amplitude of A₀ is present.

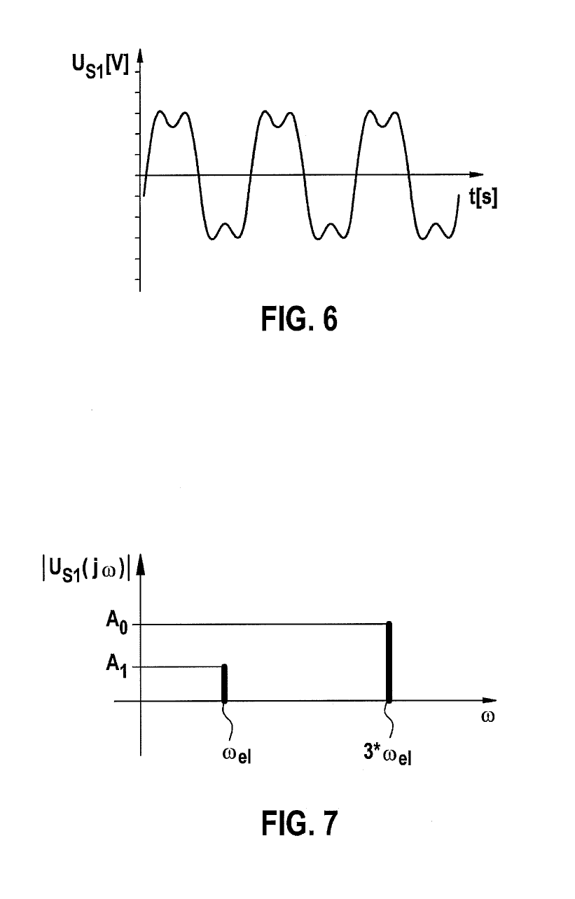

Now, in the area of 3-phase network 1, if a single phase asymmetric insulation fault occurs, that is, a deterioration of the insulation resistance in one of the three phases U, V or W, there comes about a changed curve over time of summed voltage U_{S} (cf. FIG. 6) and also a changed spectral distribution (cf. FIG. 7). In particular, in the (1-fold) electrical angular speed ωₑₗ there now appears a signal portion having a spectral amplitude of A₁, which did not appear in the fault-free case, or at least was drowned out by the noise background. Therefore, if spectral amplitude A₁ is compared to the corresponding spectral amplitude in the fault-free case that is used as reference value, that is, in this case a spectral amplitude of 0, then, in the case of a deviation, an asymmetric insulation fault may be reliably detected. The absolute amount of the amplitude change, that is, in this case, the amplitude value A1 itself, is a measure for the deterioration of the insulation resistance. In this context, as also in the detection of insulation faults still to follow, one may also, of course, specify a minimum value for the deviation, which has to be exceeded before an insulation fault is detected.

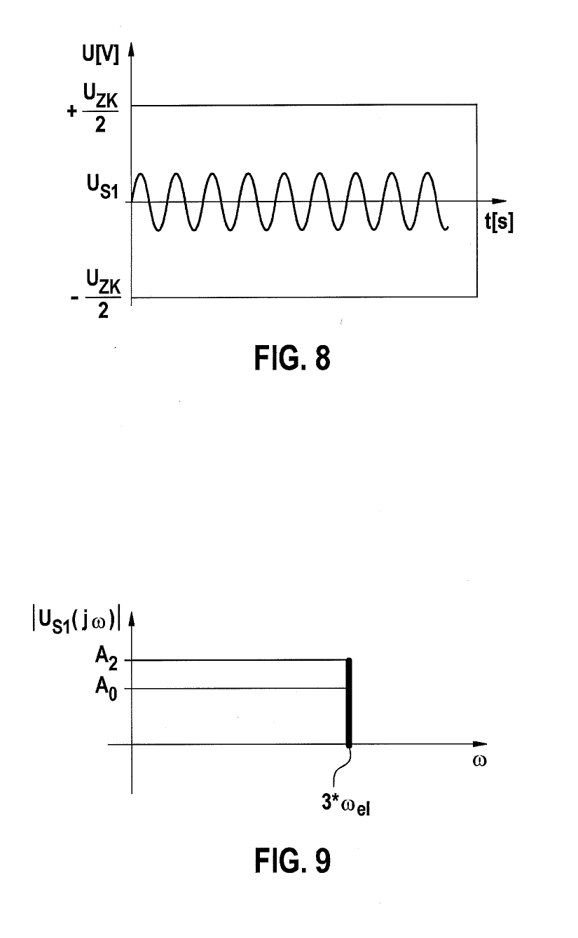

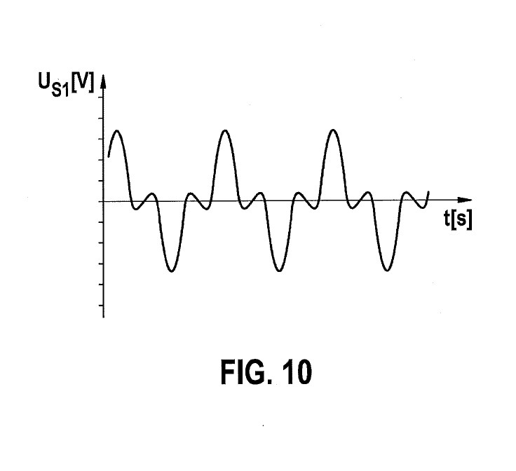

In FIGS. 8 and 9, the curve over time of summed voltage U_{S} and the spectral distribution yielded from this in response to the occurrence of a symmetric insulation fault in 3-phase network 1 are shown. In this instance, the deterioration of the insulation resistance acts on all three phases in an analogous manner. One may recognize from FIG. 9 that such an insulation fault becomes noticeable in that the spectral amplitude at 3-fold electrical angular speed 3*ωₑₗ has increased from a value of A₀ to a value of A₂. The increase in absolute amount, in this instance, is again a measure for the deterioration of the insulation resistance. By the comparison of the spectral amplitude of the 3-fold electrical angular speed 3*ωₑₗ with the corresponding spectral amplitude in the fault-free case, used as reference value, thus in this case A₀, a symmetric insulation fault is thus also able to be detected with certainty.

A similar effect is also demonstrated by the occurrence of a symmetric insulation fault in constant-voltage d.c. link 6. In this instance too, there comes about a change in the spectral distribution in the range of the 3-fold electrical angular speed 3*ωₑₗ, however, in the form of a dropping off of the amplitude value as in normal operation, that is, lower than A₀. In this case, the drop in absolute amount is a measure for the deterioration of the insulation resistance.

For the applicability of the present invention, it is only decisive to determine the spectral amplitudes at the 1-fold and 3-fold or, in the case of an n-phase network, at the n-phase electrical frequency or even the angular speed. This being the case, instead of a frequency transformation, bandpass filtration having corresponding average frequencies at ωₑₗ and 3*ωₑₗ(n*ωₑₗ) may be used, and the required amplitude values may subsequently be calculated from the filtered summed voltages.

By making additional evaluations it is also possible, besides the mere detection of an insulation fault, also to make more specific statements on the area in which the fault has appeared. This represents a diagnostic function which makes removing an fault, as for instance in a workshop, considerably simpler, since now only the specific part of the overall system has to be checked with respect to the cause of the fault.

In the case of symmetric insulation faults, by assigning the fault to constant-voltage d.c. link 6 or to n-phase network 1, no further narrowing down is possible or necessary. However, in the case of asymmetric insulation faults, things are different.

An asymmetric insulation fault in constant-voltage d.c. link 6 leads to a direct voltage offset between the potentials of the two supply voltage buses 5 and 7. When such an offset voltage occurs, which may be recognized, for example, by low-pass filtering of summed voltage U_{S}, an asymmetric fault may therefore be detected in constant-voltage d.c. link 6. By evaluating the sign of the direct voltage offset, it may then also be determined in which of the supply voltage buses 5 or 7 the insulation fault has appeared.

If voltage drop U_{Tplus-ground} between positive supply voltage potential T+ and the reference potential is less than the voltage drop U_{TMinus-ground} between negative supply voltage potential T− and the reference potential, and as a result of this summed voltage U_{S} is positive, the fault is in the area of positive supply voltage bus 5. If, on the other hand, voltage drop U_{Tplus-ground} is greater than voltage drop U_{TMinus-ground}, and thus summed voltage U_{S} is negative, the fault is in the area of negative supply voltage bus 7.

If an insulation fault is detected in 3-phase network 1, then by evaluating the phase position of the electrical frequency of summed voltage U_{S}, the phase (U, V, W) affected by the fault is able to be ascertained. For this, summed voltage US may, for instance, be bandpass filtered with the electrical frequency as average frequency, and subsequently be evaluated to the extent that the phase position coming about for summed voltage U_{S} is compared to the phase positions of the phase voltages of 3-phase network 1, that is, the voltages at phases U, V, W.

If, in the process, the result is that the electrical frequency of summed voltage U_{S} has the same phase position as the phase voltage of phase U, the insulation fault lies in the area of phase U. The corresponding applies also to the remaining phases of 3-phase network 1 or generally also to the n-phase network.

In order to be able to determine specifically two faulty phases in the 3-phase network or generally a plurality of erroneous phases in the n-phase network, at least one additional variable has to be evaluated besides the spectral amplitude of summed voltage U_{S}.

FIG. 10 shows the curve over time of summed voltage US in response to the occurrence of a two-phase asymmetric insulation fault, that is in response to a (symmetric) deterioration of the insulation resistance If the voltage curve according to FIG. 10 is compared to the voltage curve according to FIG. 6 in response to the occurrence of a single phase asymmetric insulation fault in the 3-phase network, one may recognize that the summed voltage in the case of a single phase fault has a greater energy density and also a greater effective value. In addition, the phase position in a two phase symmetric insulation fault is shifted by 60° with respect to one of the phase voltages. If the insulation fault is two-phased, but not symmetric with respect to these phases, a phase shift comes about, not equal to 60°, as a function of the difference of the size of the fault at the two phases affected.

Therefore, if besides the spectral amplitude of summed voltage U_{S} its energy content and/or its effective value and/or its phase position are evaluated, a distinction is possible between a single-phase and a two-phase insulation fault in 3-phase network 1. In addition, the specific determination of the affected phases is also possible by evaluation of the phase position. If the electrical frequency of summed voltage U_{S} is phase-shifted, for example, with respect to the phase voltage of phase U by 60°, one may conclude that there is a symmetric insulation fault, which relates to phases U and V. Analogously, a phase shift of +60° to phase V points to a symmetric insulation fault in phases V and W and a phase shift of +60° to phase W points to a symmetric insulation fault in phases U and W.

1-15. (canceled)

16. A method for monitoring insulation resistance in an ungrounded electrical network having a constant-voltage d.c. link and at least one inverter connected to it, for controlling an n-phase electrical consumer in an n-phase network, with n>1, comprising:
during operation of the consumer:
determining a voltage that is to be monitored, which represents a voltage fluctuation of supply voltage potentials of the constant-voltage d.c. link with respect to a reference potential;
determining a variable characterizing an electrical frequency of the electrical consumer;
determining a first spectral amplitude of the voltage, that is to be monitored at the n-fold electrical frequency of the electrical consumer;
comparing the first spectral amplitude of the voltage that is to be monitored, to a first reference value; and
detecting a symmetric insulation fault in one of the constant-voltage d.c. link or the n-phase network if the comparison yields a deviation of the first spectral amplitude from the first reference value.

17. The method as recited in claim 16, wherein an electrical angular speed of the electrical consumer characterizes the electrical frequency of the electrical consumer.

18. The method as recited in claim 16, further comprising:
detecting a symmetric insulation fault in the constant-voltage d.c. link if the first spectral amplitude is less than the first reference value and a symmetric insulation fault is detected in the n-phase network if the first spectral amplitude is greater than the first reference value.

19. The method as recited in claim 16, further comprising:
determining a second spectral amplitude of the voltage that is to be monitored, at the electrical frequency of the electrical consumer;
comparing the second spectral amplitude of the voltage that is to be monitored, to a second reference value; and
detecting an asymmetric insulation fault in the n-phase network if the comparison of the second spectral spectral amplitude to the second reference value yields a deviation of the second amplitude value from the second reference value.

20. The method as recited in claim 16, wherein at least one of the supply voltage potentials of the constant-voltage d.c. link is measured with respect to a reference potential and a link voltage of the constant-voltage d.c. link or both supply voltage potentials of the constant-voltage d.c. link is measured with respect to the reference potential, and from this the voltage that is to be monitored, is determined by forming the sum.

21. The method as recited in claim 16, wherein the voltage to be monitored is formed by a first measured voltage, which is measured at a center tap of a symmetric voltage divider, with respect to the reference potential, the voltage divider being connected between the supply voltage potentials of the constant-voltage d.c. link.

22. The method as recited in claim 16, further comprising:
measuring a second measured voltage at a star point with respect to a reference potential, at the star point, phases of the n-phase network being joined together via impedances; and
forming an auxiliary voltage which represents the voltage that is to be monitored by difference formation between a star point voltage, which comes about at the star point with respect to a half link voltage, and the second measured voltage.

23. The method as recited in claim 16, wherein the first reference value represents a spectral amplitude of the voltage that is to be monitored at a corresponding electrical frequency in normal operation without insulation faults.

24. The method as recited in claim 16, wherein a frequency spectrum of the voltage that is to be monitored, is formed with the aid of a fast Fourier transformation, and from this fast Fourier transformation, spectral amplitudes of the voltage that is to be monitored, is determined.

25. The method as recited in claim 24, wherein the voltage that is to be monitored is bandpass-filtered and amplitude values are determined with the aid of the filtered voltage that is to be monitored.

26. The method as recited in claim 16, further comprising:
determining a direct voltage offset between amounts of the supply voltage potentials of the constant-voltage d.c. link, and, as a function of a sign of the direct voltage offset by a low pass filtering of the voltage that is to be monitored; and
detecting an asymmetric insulation fault in a supply voltage bus of the constant-voltage d.c. link.

27. The method as recited in claim 26, wherein a phase position of the voltage that is to be monitored, and phase positions of phase voltages of the electrical consumer are determined and as a function of a relative phase position of the voltage, that is to be monitored, with respect to the phase positions of the phase voltages, at least one of: i) whether a single-phase or a multiphase asymmetric insulation fault is present in an area of the n-phase network is detected, and ii) which of the phases are affected by the insulation fault is detected.

28. The method as recited in claim 27, wherein an effective value of the voltage that is to be monitored, is determined and whether a single-phase or a multiphase asymmetric insulation fault is present in the area of the n-phase network is determined as a function of the effective value.

29. The method as recited in claim 28, wherein an energy content of the voltage that is to be monitored, is determined and whether a single-phase or a multiphase asymmetric insulation fault is present in the area of the n-phase network is determined as a function of the energy content.

30. A device for monitoring an insulation resistance in an ungrounded electrical network, the network including a constant-voltage d.c. link, an n-phase network having an n-phase electrical consumer, and at least one inverter connected to the constant-voltage d.c. link to control the electrical consumer, the device comprising:
at least two measuring devices to measure a supply voltage potential of one of the constant-voltage d.c. link and a link voltage, or two supply voltage potentials of the constant-voltage d.c. link;
a computational unit configured to determine a voltage, that is to be monitored, by forming a sum of the measured voltages, the voltage that is to be monitored representing a voltage fluctuation of the supply voltage potentials of the constant-voltage d.c. link with respect to a reference potential; and
an evaluation unit configured to determine a first spectral amplitude of the voltage to be monitored at an n-fold electrical frequency of the electrical consumer, compare the first spectral amplitude to a first reference value, and detect a symmetric insulation fault in the constant-voltage d.c. link or the n-phased network, if the comparison yields a deviation of the first spectral amplitude from the first reference value.

31. A device for monitoring insulation resistance in an ungrounded electrical network, the network including a constant-voltage d.c. link, an n-phase network having an n-phase electrical consumer, at least one inverter connected to the constant-voltage d.c. link to control the electrical consumer, and a symmetric voltage divider connected between supply voltage potentials of the constant-voltage d.c. link, the voltage divider having a center tap, the device comprising:
a measuring device to measure a variable characterizing a voltage that is to be monitored, at the center tap of the voltage divider, the voltage that is to be monitored, representing a voltage fluctuation of the supply voltage potentials of the constant-voltage d.c. link with respect to a reference potential; and
an evaluation unit configured to determine a first spectral amplitude of the voltage to be monitored at an n-fold electrical frequency of the electrical consumer, compare the first spectral amplitude to a first reference value, and detect a symmetric insulation fault in the constant-voltage d.c. link or the n-phased network, if the comparison yields a deviation of the first spectral amplitude from the first reference value.

32. A device for monitoring an insulation resistance in an ungrounded electrical network, the network including a constant-voltage d.c. link, an n-phase network having an n-phase electrical consumer, at least one inverter connected to the constant-voltage d.c. link to control the electrical consumer, and a star point at which phases of the n-phase network are joined via the impedances, the device comprising:
a measuring device to measure a variable characterizing a second measured voltage at the star point with respect to a reference potential;
a computational unit to form an auxiliary voltage by a difference formation between a star point voltage, which comes about at the star point with respect to a half link voltage, and the second measured voltage, the auxiliary voltage representing a voltage fluctuation of supply voltage potentials of the constant-voltage d.c. link with respect to a reference potential; and
an evaluation unit configured to determine a first spectral amplitude of the voltage to be monitored at an n-fold electrical frequency of the electrical consumer, compare the first spectral amplitude to a first reference value, and detect a symmetric insulation fault in the constant-voltage d.c. link or the n-phased network, if the comparison yields a deviation of the first spectral amplitude from the first reference value.
